(19) United States
(12) Patent Application Publication
(10) Pub. No.: US 2003/0091124 A1
(43) Pub. Date: May 15, 2003

(54) Slicer circuit with ping pong scheme for data communication

(75) Inventors: Dev Vrat Gupta, Concord, MA (US); Miaochen Wu, Acton, MA (US); Xiangdong Zhang, Westford, MA (US); Wei Ye, Westford, MA (US)

Correspondence Address: Leo R. Reynolds, Esq., HAMILTON, BROOK, SMITH & REYNOLDS, P.C., 530 Virginia Road, P.O. Box 9133, Concord, MA, 01742-9133, US

(73) Assignee: Narad Networks, Inc., Westford, MA

(21) Appl. No.: 10/012,681

(22) Filed: Nov. 13, 2001

(51) Int. Cl. H03K 9/00; H04L 27/06

(52) U.S. Cl. 375/316; 375/355

(57) ABSTRACT

A ping-pong scheme is used to slow down data transfer speed between an analog slicer in a receiver and a digital physical layer device, while maintaining the same data throughout. Two edges of a clock are used to slice the incoming analog signal, convert the analog signal to a digital signal and latch the converted signal. A ping-pong data pipeline is provided from the analog slicer to the physical layer device.

### RELATED APPLICATION(S)

This application is related to Attorney Docket No. 3070.1008-000 entitled “Frequency Acquisition and Locking Detection Circuit for Phase Lock Loop” by Miaochen Wu, et al., Attorney Docket No.: 3070.1009-000 entitled “Automatic Gain Control Circuit With Multiple Input Signals”, by Miaochen Wu, and Attorney Docket No. 3070.1010-000 entitled “Differential Slicer Circuit for Data Communication”, by Miaochen Wu, filed on even date herewith. The entire teachings of the above applications are incorporated herein by reference.

### BACKGROUND OF THE INVENTION

A broadband modem typically transmits data at data rates greater than 10 Mbps over a coaxial cable. A cable modem can use Quadrature Amplitude Modulation (QAM) to obtain a high data rate. Quadrature Amplitude Modulation (QAM) is a method for doubling effective bandwidth by combining two Amplitude Modulated carriers in a single channel. Each of the two carriers in the channel has the same frequency but differs in phase by 90 degrees. One carrier is called the In-phase (I) signal and the other carrier is called the Quadrature (Q) signal.

The receiver recovers the I and Q signals from the received QAM signal and extracts the data encoded on each signal. To extract the data, the analog I and Q signals are converted into a digital encoded signal. A slicer circuit is typically used to convert data encoded on the I and Q signals into the digital encoded signal.

### SUMMARY OF THE INVENTION

The encoded signal output by the slicer circuit is typically coupled to a digital processing device for further data processing. The slicer circuit is operated at the same speed as the digital processing device but the slicer circuit can be operated much faster than the digital processing device. Thus, the data throughput of the slicer circuit is dependent on the speed of the digital processing device.

The invention provides a ping-pong scheme to slow down data transfer between an analog slicer circuit in a receiver and a digital processing device while maintaining the data throughput of the slicer circuit. In the analog slicer circuit, two edges of a clock, the rising edge and falling edge, are used to slice the incoming analog signal, convert the analog signal to a digital signal and to latch the converted digital signal. The latched converted digital signal is sent at the same overall speed as the received data to two receivers operating at half the speed of the clock in the digital processing device.

To latch the converted digital data, the slicer circuit in the receiver includes a first latch and a second latch coupled to a data signal. The first latch latches and sends a first data from the data signal on a rising edge of a clock. The second latch latches and sends a second data from the data signal on a falling edge of the clock. The first and second data are sent in parallel to a next stage at the same overall speed as the data received on the data signal. No buffer is required in the slicer circuit to slow down data transfer speed because each latch sends and receives so that the data throughput is maintained through the slicer circuit.

The frequency of the clock is half of the frequency of the data signal. The first latch includes a first stage latch and a second stage latch. The second stage latch is coupled to the first stage latch. The first stage tracks data from the data signal and the second stage latch latches and sends the latched data on the rising edge of the clock. The second latch includes a first stage latch and a second stage latch. The second stage latch is coupled to the first stage latch. The first stage tracks data from the data signal and the second stage latch latches and sends the latched data on the falling edge of the clock.

The slicer circuit also includes a first encoder coupled to the first latch and a second encoder coupled to the second latch. The encoders output an encoded first data and encoded second data from the first latch and the second latch for use by the digital processing device.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 illustrates an embodiment of a network configuration of intelligent network elements for providing point-to-point data links between intelligent network elements in a broadband, bidirectional access system;

FIG. 2 is a block diagram of an embodiment of any one of the network elements shown in FIG. 1;

FIG. 3 is a block diagram of a receiver in any of the modems in the network element shown in FIG. 2;

FIG. 4 is a block diagram of a differential slicer circuit in the ADC stage shown in FIG. 3 according to the principles of the present invention;

FIG. 5 is a block diagram of the differential slicer circuit shown in FIG. 4 including the differential comparators, latches and encoders;

FIG. 6 is a block diagram illustrating one of the A latches and one of the B latches shown in FIG. 5; and

FIG. 7 is a timing diagram illustrating the processing of data in the differential slicer circuit shown in FIGS. 5 and 6.

### DETAILED DESCRIPTION OF THE INVENTION

A description of preferred embodiments of the invention follows.

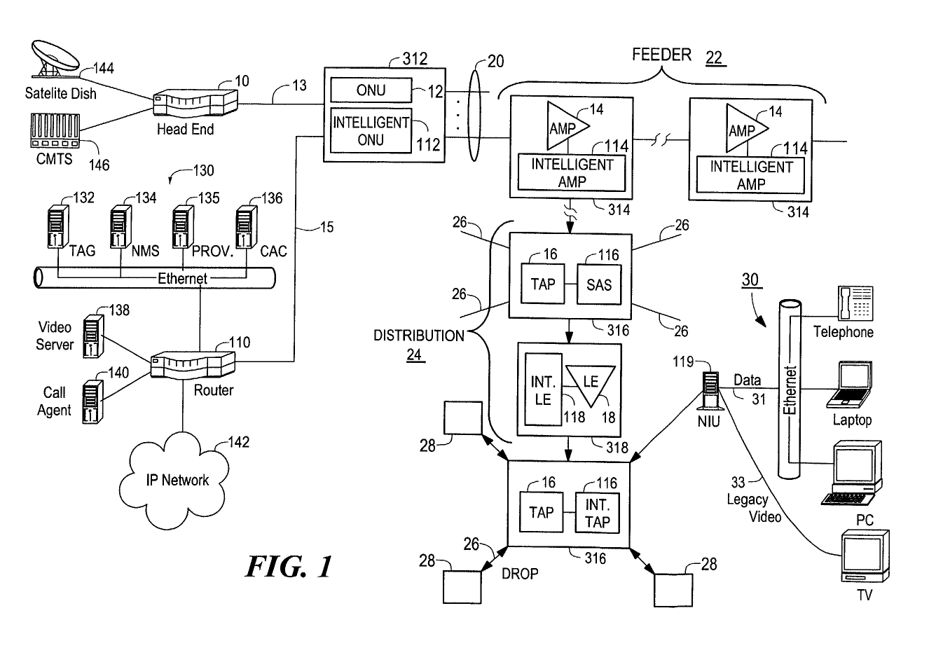

FIG. 1 illustrates an embodiment of a network configuration of intelligent network elements for providing point to point data links between intelligent network elements in a broadband, bidirectional access system. This network configuration is described in U.S. patent application Ser. No. 09/952,321 filed Sep. 13, 2001 entitled “Broadband System With Topology Discovery”, by Gautam Desai, et al, the entire teachings of which are incorporated herein by reference. The network configuration, also referred to herein as an Access Network, includes intelligent network elements each of which uses a physical layer technology that allows data connections to be carried over coax cable distribution facilities from every subscriber. In particular, point-to-point data links are established between the intelligent network elements over the coax cable plant. Signals are terminated at the intelligent network elements, switched and regenerated for transmission across upstream or downstream data links as needed to connect a home to the headend.

The intelligent network elements are interconnected using the existing cable television network such that the point-to-point data links are carried on the cable plant using bandwidth that resides above the standard upstream/downstream spectrum. For example, the bandwidth can reside at 1025 to 1125 MHZ (upstream) and 1300 to 1400 MHZ (downstream) or 100 Mbps upstream and downstream bandwidths can be provided in the spectrum 750 to 860 MHZ or duplexing channel spectrums can be allocated in the 777.5 MHz to 922.5 MHz regime for 100 Mb/s operation and in the 1 GHz to 2 GHz regime for 1 Gb/s operation.

The intelligent network elements include an intelligent optical network unit or node 112, intelligent trunk amplifier 114, intelligent tap or subscriber access switch (SAS) 116, intelligent line extender 118 and network interface unit (NIU) 119. A standard residential gateway or local area network 30 connected to the NIU 119 at the home is also shown. Note that the trunk amplifier 114 is also referred to herein as a distribution switch (DS). The configuration shown includes ONU assembly 312 comprising standard ONU 12 and intelligent ONU 112 also referred to herein as an optical distribution switch (ODS). Likewise, trunk amplifier or DA assembly 314 includes conventional trunk amp 14 and intelligent trunk amp 114; cable tap assembly 316 includes standard tap 16 and subscriber access switch 116; and line extender assembly 318 includes standard line extender 18 and intelligent line extender 118.

The intelligent ONU or ODS is connected over line 15 to a router 110, which has connections to a server farm 130, a video server 138, a call agent 140 and IP network 142. The server farm 130 includes a Tag/Topology server 132, a network management system (NMS) server 134, a provisioning server 135 and a connection admission control (CAC) server 136, all coupled to an Ethernet bus which are described in U.S. patent application Ser. No. 09/952,321 filed Sep. 13, 2001 entitled “Broadband System With Topology Discovery”, by Gautam Desai, et al, the entire teachings of which are incorporated herein by reference.

A headend 10 is shown having connections to a satellite dish 144 and CMTS 146. To serve the legacy portion of the network, the headend 10 delivers a conventional amplitude modulated optical signal to the ONU 12. This signal includes the analog video and DOCSIS channels. The ONU performs an optical to electrical (O/E) conversion and sends radio frequency (RF) signals over feeder coax cables 20 to the trunk amplifiers or DAs 14. Each DA along the path amplifies these RF signals and distributes them over the distribution portion 24.

The present system includes intelligent network elements that can provide high bandwidth capacity to each home. In the Access Network of the present invention, each intelligent network element provides switching of data packets for data flow downstream and statistical multiplexing and priority queuing for data flow upstream. The legacy video and DOCSIS data signals can flow through transparently because the intelligent network elements use a part of the frequency spectrum of the coax cable that does not overlap with the spectrum being used for legacy services.

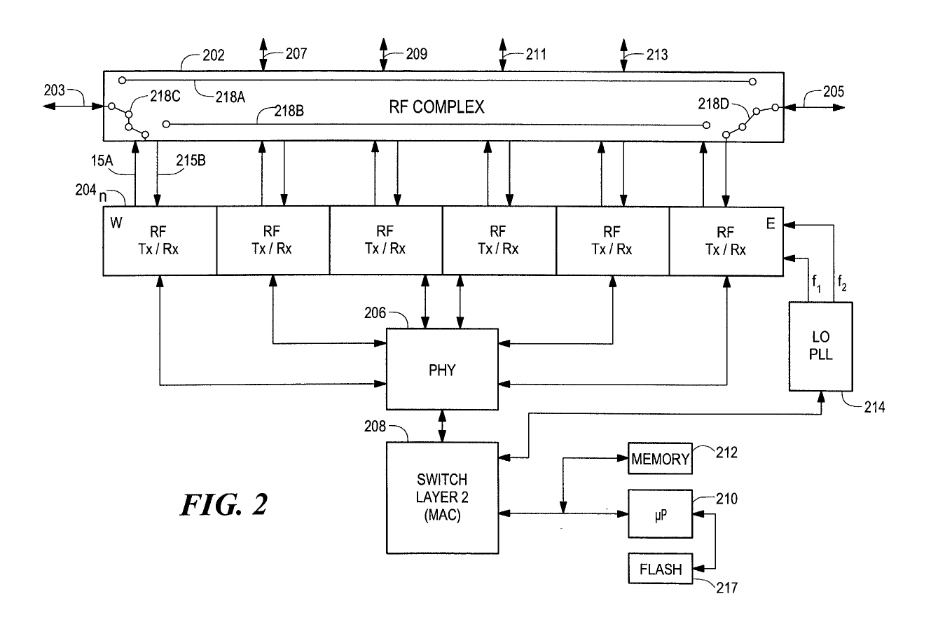

FIG. 2 is a block diagram of an embodiment of any one of the network elements shown in FIG. 1. The network element includes an RF complex 202, RF transmitter/receiver pairs or modems 204a-204n, a PHY (physical layer) device 206, a switch 208, microprocessor 210, memory 212, flash memory 217 and a local oscillator/phase locked loop (LO/PLL) 214. All of the components are common to embodiments of the ODS, DS, SAS and NIU shown in FIG. 1. The ODS further includes an optical/electrical interface. The NIU further includes a 100BaseT physical interface for connecting to the Home LAN 30 (FIG. 2). In addition, the RF complex is shown as having a bypass path 218A and a built in self test path 218B controlled by switches 218C, 218D which are described further herein.

The number of modems, 204n generally, depends on the number of links that connect to the network element. For example, DS 314 (FIG. 1) has five ports and thus has five modems 204. A SAS 316 (FIG. 1) has six ports and thus has six modems 204. The network element in FIG. 2 is shown having six ports indicated as ports 203, 205, 207, 209, 211 and 213.

The PHY device 206 provides physical layer functions between each of the modems 204 and the switch 208. The switch 208, controlled by the microprocessor 210, provides layer 2 switching functions and is referred to herein as the Media Access Control (“MAC”) device or simply MAC. The LO/PLL 214 provides master clock signals to the modems 204 at the channel frequencies.

A modulation system with spectral efficiency of 4 bits/s/Hz is used in the RF modem 604n (FIG. 2) to provide high data rates within the allocated bandwidth. In particular, 16-state Quadrature Amplitude Modulation (16-QAM) is preferably used, which involves the quadrature multiplexing of two 4-level symbol channels. Embodiments of the network elements of the present system described herein support 100 Mb/s and 1 Gb/s Ethernet transfer rates, using the 16-QAM modulation at symbol rates of 31 or 311 MHZ.

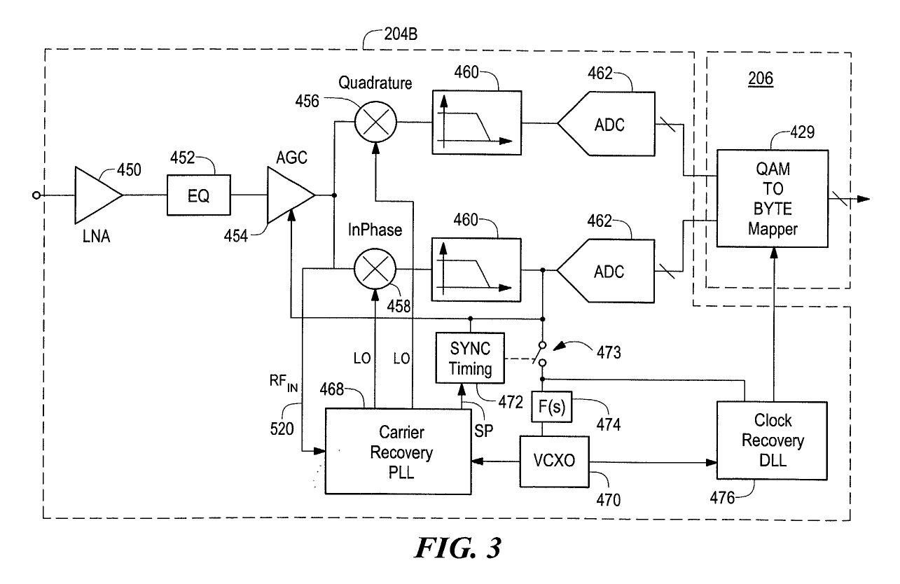

FIG. 3 is a block diagram of a receiver 204B in any of the modems 204 in the network element shown in FIG. 2. The receiver 204B receives a quadrature-multiplexed signal which includes in-phase (I) and quadrature (Q) carriers. At the front end, the receiver section 204B includes low-noise amplifier (LNA) 450, equalizer 452 and automatic gain control (AGC) 454. The received signal from PHY 206 (FIG. 2) is boosted in the LNA 450 and corrected for frequency-dependent line loss in the equalizer 452. The equalized signal is passed through the AGC stage 454 to I and Q multiplier stages 456, 458, low pass filters 460 and analog-to-digital converters (ADC) 462. After down-conversion in the multiplier stages 456, 458 and low-pass filtering, the I and Q channels are digitized and passed on to a QAM-to-byte mapper 429 for conversion to a byte-wide data stream in the Physical Layer (PHY) device 406 (FIG. 2).

Carrier and clock recovery, for use in synchronization at symbol and frame levels, are performed during periodic training periods. A carrier recovery PLL circuit 468 provides the I and Q carriers from the RF carrier (RFin) 520 to the multipliers 456, 458. The RF carrier 520 includes the I and Q carriers. A clock recovery delay locked loop (DLL) circuit 476 provides a clock to the QAM-to-byte mapper 449. During each training period, PLL and DLL paths that include F(s) block 474 and voltage controlled oscillator (VCXO) 470 are switched in using normally open switch 473 under control of SYNC timing circuit 472 in order to provide updated samples of phase/delay error correction information.

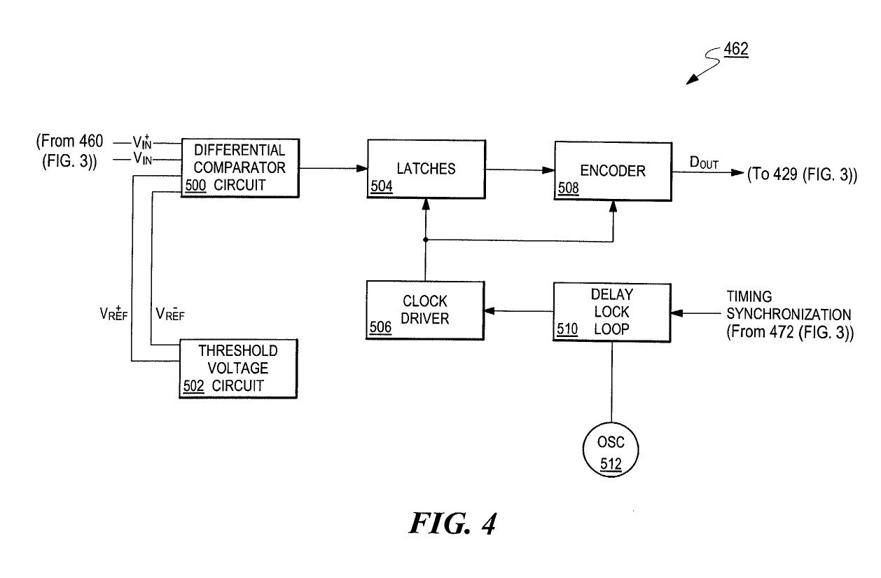

FIG. 4 is a block diagram of a slicer circuit in the ADC 462 shown in FIG. 3 according to the principles of the present invention. The ADC 462 includes a differential comparator circuit 500, a threshold voltage circuit 502, latches 504, a clock driver 506, an encoder 508, a delay lock loop 510 and an oscillator 512.

The differential comparator circuit 500 includes at least one differential comparator for comparing the input signal Vᵢₙ⁺, Vᵢₙ⁻ received from the low pass filter 460 (FIG. 3) with a differential threshold voltage provided by the threshold voltage circuit 502.

The result of the comparison in the differential comparator circuit 500 is a thermometer coded output signal which is coupled to latches 504. The thermometer coded signal is latched in the latches dependent on a clock output by the clock driver 506. The clock is dependent on an oscillator 512 synchronized with the input signal Vᵢₙ⁺, Vᵢₙ⁻ by timing synchronization coupled to the delay lock loop 510. The timing synchronization is under control of the sync timing circuit 472 (FIG. 3).

The differential comparator circuit 500 is described in co-pending U.S. patent application Attorney Docket No. 3070.1010-000 entitled “Differential Slicer Circuit for Data Communication”, by Miaochen Wu, filed on even date herewith, the entire teachings of which are incorporated herein by reference. The output of the latches 504 is coupled to the encoder 508. The encoder 508 converts the latched thermometer coded output signal to a binary encoded digital signal which is coupled to the QAM to Byte Mapper 429 (FIG. 3) in the PHY device 206 (FIG. 3).

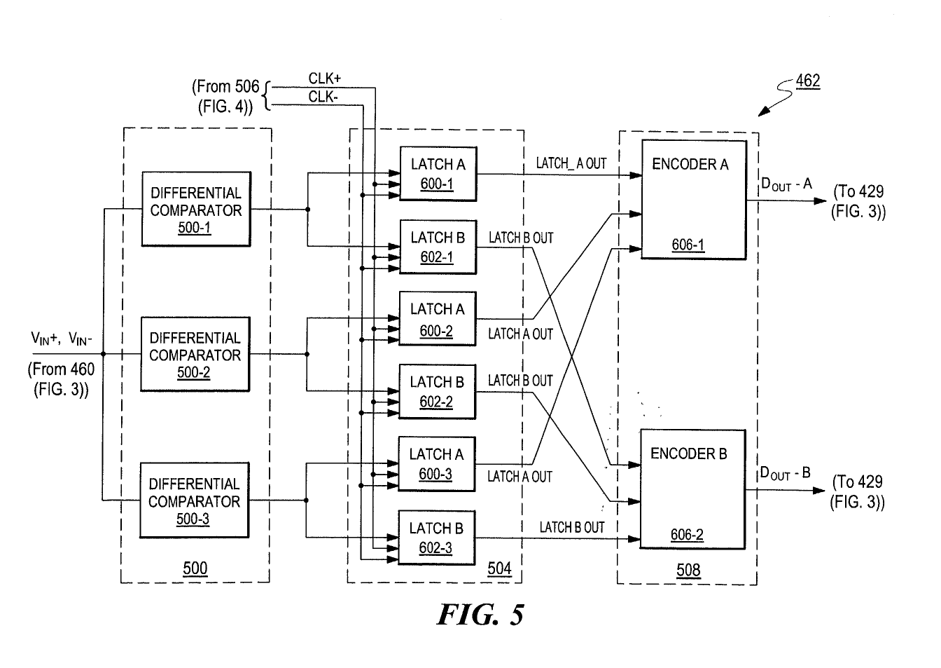

FIG. 5 is a block diagram of the differential comparator circuit 500, latches 504 and encoder 508 in the slicer circuit shown in FIG. 4 according to the principles of the present invention. The differential comparator circuit 500 includes three differential comparators 500-1, 500-2, 500-3. However, the invention is not limited to a differential comparator circuit 500 with three differential comparators. There can be more or less than three differential comparators.

Latches 504 includes a respective A-latch 600-1, 600-2, 600-3 and respective B-latch 602-1, 602-2, 602-3 for each differential comparator 500-1, 500-2, 500-3 in the differential comparator circuit 500. Each A-latch 600-1, 600-2, 600-3 and B-latch 6021, 602-2, 602-3 is coupled to a differential latches clock CLK+, CLK−. A rising edge on CLK+ corresponds to a falling edge on CLK−. The latches clock CLK+, CLK− is coupled to the A-latch 600-1, 600-2, 600-3 and the B-latch 602-1, 602-2, 602-3, so that data is latched in the A-latch on a rising edge and data is latched in the B-latch on a falling edge of the latches clock CLK+, CLK−.

The outputs of A latches 600-1, 600-2, 600-3 are coupled to an A-encoder 606-1 and the outputs of B latches 602-1, 602-2, 602-3 are coupled to a B encoder 606-2. The outputs of the encoders are coupled to two receivers in the QAM to Byte Mapper 429 (FIG. 3).

The frequency of the latches clock CLK+, CLK− is half the frequency of the data received on the input signal Vᵢₙ⁺, Vᵢₙ⁻. However, the data is sent to the QAM to Byte Mapper 429 at the same overall speed by forwarding the data on parallel paths with the data latched in the A latch forwarded to one receiver and the data latched in the B latches forwarded to the other receiver. The data is forwarded on each of the parallel paths at half the frequency at which it is received. By providing parallel paths, the A and B data is sent to the QAM to Byte Mapper 429 at the same frequency at which it is received. Thus, data is received at the rate at which the slicer circuit can process the data and forwarded on each of the parallel paths at the rate at which the receivers in the PHY device can process it. The received data is latched and forwarded through A latches 600-1, 600-2, 600-3 and B latches 602-1, 602-2, 602-3 without requiring that the received data be first stored in a buffer. Thus, the A latch and B latch allows the slicer circuit to operate at the frequency of the received data and the QAM to Byte Mapper 429 (FIG. 3) to operate at half the frequency of the received data.

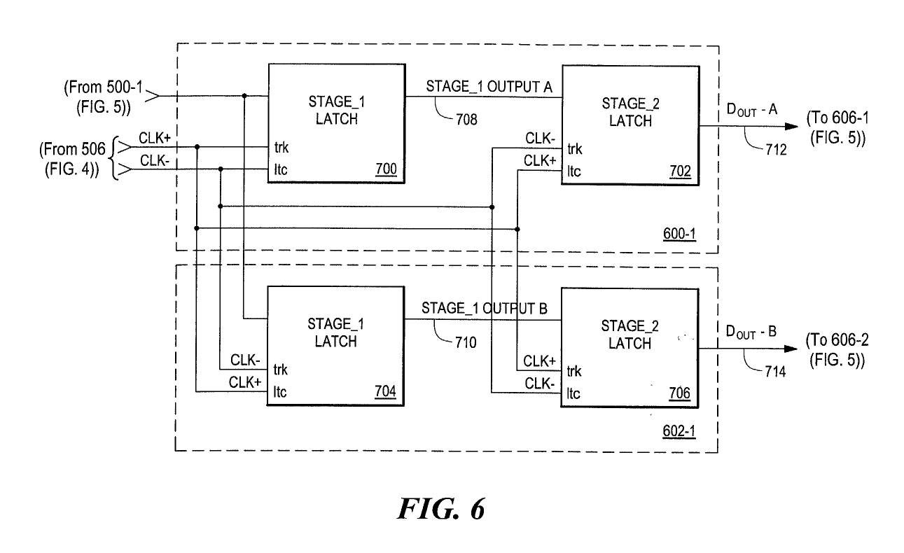

FIG. 6 is a block diagram illustrating one of the A latches 600-1 and one of the B latches 602-1 shown in FIG. 5. Each latch 600-1, 602-1 includes a respective stage-i latch 700, 704 and a respective stage 2 latch 702, 706. The data received from the differential comparator circuit 500-1 is coupled to the input of the respective stage-1 latch 700, 702. The stage_{—}1 data output 708, 710 from the respective stage-1 latch 700, 702 is coupled to the input of the respective stage_{—}2 latch 701, 706. The data at the input of the stage-1 latch 700, 702 tracks the received data to output the received data on the respective stage-1 output 708, 710. The outputs 714, 716 of the respective stage_{—}2 latch 702, 706 are coupled to the respective encoders shown in FIG. 5.

Each of the two stage latches acts like a D-type flip flop. In a D-type flip-flop, the output only changes on a clock edge (rising or falling). Referring to latch 600-1, CLK+ is coupled to the tracking input of the stage_{—}1 latch 700 and to the latching input of the stage_{—}2 latch 702. CLK− is coupled to the tracking input of the stage-2 latch 702 and to the latching input of the stage_{—}2 latch 700. After the falling and rising edges of the latches clock CLK+, CLK−, the stage 1 latch 700 and the stage 2 latch 702 are in tracking mode. As the data at the input of the stage_{—}1 latch 700 is tracked, the stage 1 output data A 708 changes at the input data changes. The tracked input on stage 1 output data A 708 is latched in the stage 2 latch 702 and sent on Dout A to encoder A on the rising edge of the latches clock CLK+, CLK−.

Referring to latch B 602-1, CLK− is coupled to the tracking input of the stage 1 latch 704 and to the latching input of the stage 2 latch. CLK+ is coupled to the tracking input of the stage 2 latch 706 and to the latching input of the stage 1 latch 704. After the falling and rising edges of the latches clock CLK+, CLK−, the stage 1 latch 704 and the stage 2 latch 706 are in tracking mode. As the data at the input of the stage 1 latch 704 is tracked, the stage 1 output data B 710 changes at the input data changes. The tracked input on stage 1 output data B 710 is latched in the stage 2 latch 706 and sent on Dout B to encoder B on the falling edge of the latches clock CLK+, CLK−. Thus, A-data is latched and sent by latch 600-1 on the rising edge of latches clock CLK+ CLK− and B-data is latched and sent by latch 602-1 on the falling edge of latches clock CLK+, CLK−.

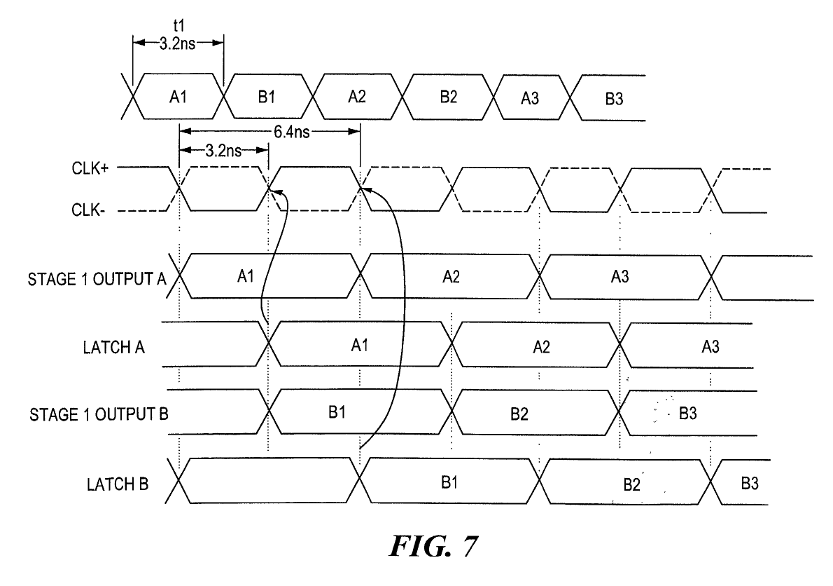

FIG. 7 is a timing diagram illustrating the processing of data in the differential slicer circuit shown in FIGS. 5 and 6. In an embodiment in which data is received on the input signal Vᵢₙ⁺, Vᵢₙ⁻ at 311 Mega bits per second (Mbps), data is received every 3.2 nano seconds (ns) (1/311×10⁶)). Data is received on the input signal Vᵢₙ⁺, Vᵢₙ⁻ by the differential comparator circuit 500 every 3.2 ns. The frequency of the differential latches clock CLK+, CLK− is half the frequency of the received data; that is, the clock period of the differential latches clock CLK+, CLK− is 6.4 ns. The time between a rising and falling edge of the latches clock CLK+, CLK− is therefore 3.2 ns, the time to receive one data bit on the input signal Vᵢₙ⁺, Vᵢₙ⁻.

The frequency of the data forwarded to the QAM to Byte Mapper 429 (FIG. 4) is reduced by latching alternate data bits in two latches, latch A 600-1, 600-2, 6003 and latch B 602-1, 602-2, 602-3, to output the data bits on two parallel data paths. The frequency of the forwarded data on each path is half the frequency of the received data.

Referring to the path through differential comparator 500-1, latch A 600-1 (stage 1 latch 700 and stage 2 latch 702) and latch B 602-1 (stage 1 latch 704 and stage 2 latch 706). In received data period t1, data A1 is received from the differential comparator 500-1 at the input of the state-1 latch 700 in latch A 600-1. The A1 data is tracked by the stage 1 latch 700 in latch 600-1 after the falling edge of CLK+ and is output on stage 1 output A 708. The next rising edge of CLK+ latches the tracked Al data on stage 1 output data A 708 into the state 2 latch 702 in latch A 600-1 and sends the A1 data to encoder 606-1 on Dout-A 712.

The next rising edge of CLK− which corresponds to the falling edge of CLK+, the B1 data is received at the input of stage 1 latch 704 in latch B 602-1 from the differential comparator 500-1. The B1 data is tracked by the stage 1 latch 704 in latch B 602-1 after the rising edge of CLK+ and output on the stage 2 output B 710. The rising edge of CLK− latches the tracked B1 data on stage 2 output B 710 into the stage 2 latch 706 in latch B 602-2 and sends the B1 data to encoder B 606-2 on Dout-B 714.

Thus, the latches 600-1, 600-2 provide a ping-pong data pipeline from the analog slicer to the PHY device. No buffer is required in the slicer circuit 462 because each latch 600-1, 600-2 sends and receives so that the data throughput of the received data is maintained through the slicer circuit 462. Also, by latching and sending A data on the rising edge of the latches clock CLK+, CLK− and latching and sending B data on the falling edge of the latches clock CLK+, CLK−, noise created by the latches is spread evenly between the falling edge and the rising edge of the latches clock CLK+, CLK−.

While this invention has been particularly shown and described with references to preferred embodiments thereof, it will be understood by those skilled in the art that various changes in form and details may be made therein without departing from the scope of the invention encompassed by the appended claims.

What is claimed is:

1. A slicer circuit in a receiver comprising:
a first latch coupled to a data signal, the first latch latching and sending a first data from the data signal on a rising edge of a clock; and
a second latch coupled to the data signal, the second latch latching and sending a second data from the data signal on a falling edge of the clock, the first and second data sent in parallel to a next stage at the same speed as the data received on the data signal.

2. The slicer circuit as claimed in claim 1 wherein the frequency of the clock is half of the frequency of the data signal.

3. The slicer circuit as claimed in claim 1 wherein the first latch and the second latch further comprises:
a first stage latch; and
a second stage latch coupled to the output of the first stage latch, the first stage latch tracking data on the data signal and the second stage latch latching the tracked data and sending the latched data on the rising edge of the clock.

4. The slicer circuit as claimed in claim 3 wherein the second latch further comprises:
a first stage latch; and
a second stage latch coupled to the output of the first stage latch, the first stage latch tracking data on the data signal and the second stage latch latching the tracked data and sending the latched data on the falling edge of the clock.

5. The slicer circuit as claimed in claim 1 further comprising:
a first encoder coupled to the first latch; and
a second encoder coupled to the second latch, the encoders outputting an encoded first data and encoded second data from the first latch and the second latch.

6. A method for reducing data transfer speed in a slicer comprising:
latching and sending a first data received on a data signal on a rising edge of a clock;
latching and sending a second data received on the data signal on a falling edge of the clock; and
forwarding the first data and second data on parallel paths to a next stage at the same speed as the received data signal.

7. The method as claimed in claim 6 wherein the frequency of the clock is half of the frequency of the data signal.

8. The method as claimed in claim 6 wherein the step of latching and sending the first data further comprises:
tracking data received on the data signal;
latching the tracked data on the rising edge of the clock; and
sending the latched data on the rising edge of the clock.

9. The method as claimed in claim 8 wherein the step of latching and sending the second data further comprises:
tracking data received on the data signal;
latching the tracked data on the falling edge of the clock; and
sending the latched data on the falling edge of the clock.

10. The method as claimed in claim 6 further comprising encoding data received in parallel from the first data and second data.

11. A slicer circuit in a receiver comprising:
means for latching and sending a first data received on a data signal on a rising edge of a clock;
means for latching and sending a second data received on the data signal on a falling edge of the clock; and
means for forwarding the first data and second data on parallel paths to a next stage at the same speed as the received data signal.

12. The slicer circuit as claimed in claim 11 wherein the frequency of the clock is half of the frequency of the data signal.

13. The slicer circuit as claimed in claim 12 wherein the means for latching and sending the first data further comprises:
means for tracking data received on the data signal; and
means for latching the tracked data and sending the latched data on the rising edge of the clock.

14. The slicer circuit as claimed in claim 13 wherein the means for latching and sending the second data further comprises:
means for tracking data received on the data signal; and
means for latching the tracked data and sending the latched data on the falling edge of the clock.

15. The slicer circuit as claimed in claim 11 further comprising:
means for encoding data received in parallel from the first data and second data.
